(19) United States
(12) Patent Application Publication
(10) Pub. No.: US 2026/0160845 A1
(43) Pub. Date: Jun. 11, 2026

(54) PHASE IDENTIFICATION TESTS AND INDICES

(71) Applicant: Itron, Inc., Liberty Lake, WA (US)

(72) Inventors: Yingjuan Du, San Diego, CA (US); Brendan Stellarum, San Diego, CA (US)

(21) Appl. No.: 18/975,071

(22) Filed: Dec. 10, 2024

(51) Int. Cl. G01R 35/04; G01R 25/00

(52) U.S. Cl. CPC G01R 35/04; G01R 25/00

(57) ABSTRACT

A method, apparatus, and system for determining validity of phase assignments by a phase identification model are disclosed. For example, the method includes predicting a phase correlated with each electricity meter of a plurality of electricity meters based on voltage time series data collected over a preselected collection time period, the phase being one of a first phase, a second phase, or a third phase; selecting a reliability parameter associated with predicted phases of the plurality of electricity meters; determining whether a parameter value associated with the reliability parameter meets a threshold parameter value; based on determining that the parameter value meets the threshold parameter value, determining that the predicted phases of the plurality of electricity meters are valid; and based on determining that the parameter value fails to meet the threshold parameter value, determining that the predicted phases of the plurality of electricity meters are invalid.

### TECHNICAL FIELD

The present disclosure generally relates to the field of phase-balancing, and more specifically to a method and system for providing phase identification tests and indices for accuracy of predicted phases of electricity meters connected to an electrical grid.

### BACKGROUND

Phase-balancing, such as balancing the electrical load on each of three electrical phases, in an electrical grid is an important consideration for utility providers. Phase-balancing may be complicated if electrical utility company records are incorrect, which frequently happens. For example, when linemen move a customer's connection, i.e., moving the customer's electricity meter from one phase to another to better balance the load, the linemen may fail to record their actions and update the phase information of the customer's meter. Poorly balanced load reduces operational efficiency, and increases the likelihood of equipment failure and delays power outage management. While phases associated with electricity meters may be predicted, accuracy of the predicted phases may not be known and may require field verification.

An improved and/or correct understanding of the topology has many advantages for advanced metering infrastructure (AMI) having automated meter reading (AMR) and other features associated with smart electricity meters. Correct understanding of the phase of a meter can help to improve an understanding of the topology of the electrical grid.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items or features.

FIG. 1 illustrates an example power distribution environment.

FIG. 2 illustrates a schematic diagram of an example transformer.

FIG. 3 illustrates an example set of voltage graphs for various phases.

FIGS. 4A and 4B illustrate an example process of a phase identification model for identifying a phase at an electricity meter level.

FIG. 5 illustrates an example detail process of one of the blocks of FIG. 4.

FIG. 6 illustrates an example detail process of another block of the blocks of FIG. 4.

FIG. 7A illustrates an example display of the clusters of electricity meters.

FIG. 7B illustrates an example display of a phase map of the electricity meters of FIG. 7A.

FIGS. 8A and 8B illustrate example plots having non-120° separation angles between adjacent phase lines.

FIG. 9 illustrates an example plot of minimum separation angle vs. maximum separation angle for analyzing the angle index.

FIG. 10 illustrates the same data used in FIG. 9 expressed as an example histogram of angle indices.

FIG. 11 illustrates an example process for determining validity of phase assignments by the phase identification model.

FIG. 12 illustrates first example detail processes of two of the blocks of FIG. 11.

FIG. 13 illustrates second example detail processes of two of the blocks of FIG. 11.

FIG. 14 illustrates third example detail processes of two of the blocks of FIG. 11.

FIG. 15 illustrates fourth example detail processes of two of the blocks of FIG. 11.

FIG. 16 illustrates an example block diagram of a system for determining validity of phase assignments by the phase identification model.

### DETAILED DESCRIPTION

Systems and methods for identifying a phase connected to electricity meters are disclosed.

Electricity is generated in three phases, A, B, and C; and on each phase, voltage oscillates in a sine wave, for example, at 60 Hz. Each of three phases of electricity is transmitted on a separate power line and there may be a fourth line, N, a ground or neutral wire with no voltage on it. These lines interact with each other at transformers, or where power is consumed.

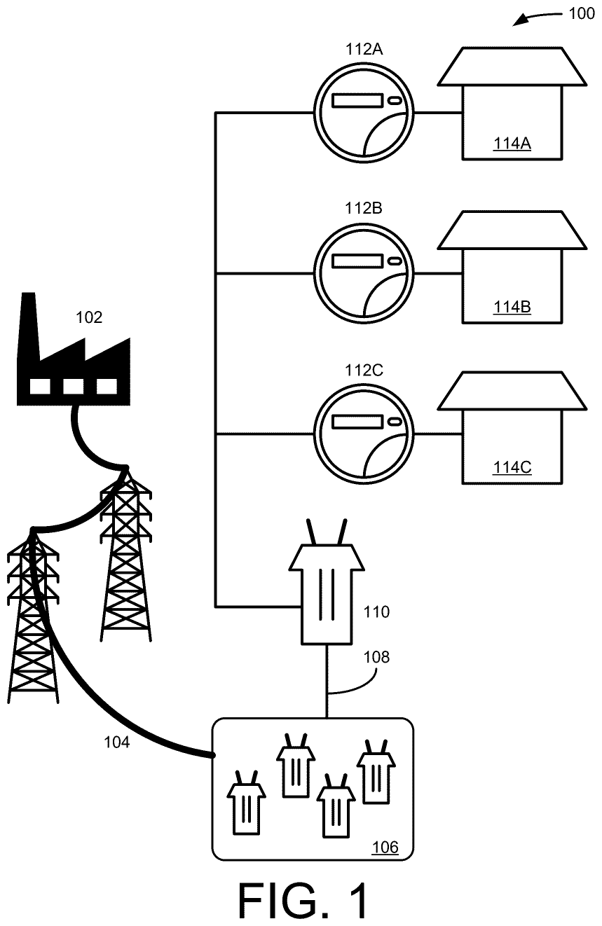

FIG. 1 illustrates an example power distribution environment 100. In this example, a power plant 102 generates electricity, which is carried by high voltage lines 104 to a power substation 106. The power substation 106 provides electricity via a feeder 108 to a transformer 110. The feeder 108 is a power line consisting of individual powered lines with Phase A, B, and C servicing a plurality of premises connected via the transformer 110 and electricity meters 112A, 112B, and 112C providing electricity to associated premises 114A, 114B, and 114C.

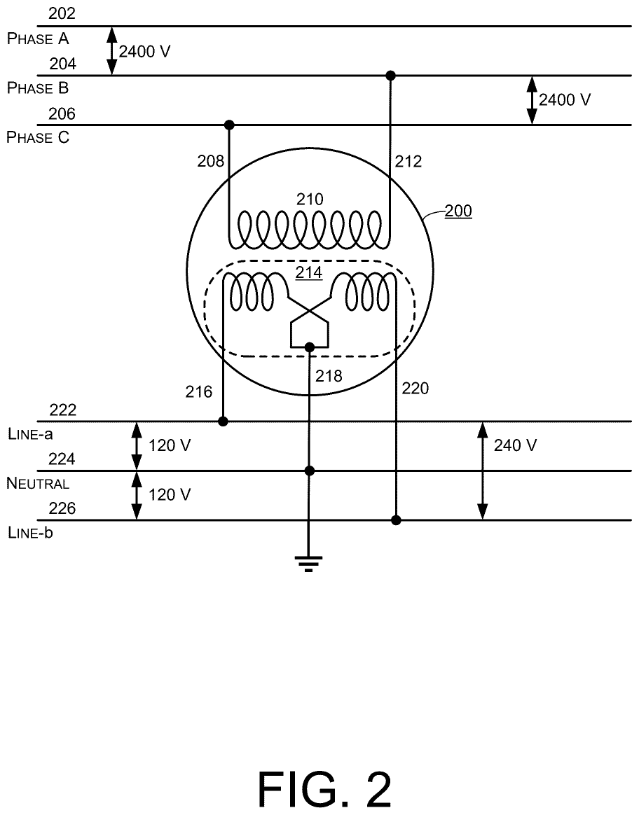

FIG. 2 illustrates a schematic diagram of an example transformer 200, such as a distribution transformer. Transformers are used to adjust voltage, and can be wired between a powered line and the neutral line, in which case, an output phase corresponds to the phase of the powered line. The transformers can also be wired between two powered lines, in which case, an output phase differs from all three powered lines and may be referred to as a hybrid phase. Therefore, there are six possible phases at the metering level: Phase A-N(or A), Phase B-N (or B), Phase C-N (or C), Phase A-B, Phase B-C, and Phase A-C. In this example, Phases A, B, and C are shown as on lines 202, 204, and 206, respectively. In this example, there are 2400 V between Phases A 202 and B 204 and between Phases B 204 and C 206, and a first connection 208 of a primary winding 210 of the transformer 200 is connected to Phase C 206 and a second connection 212 of the primary winding 210 is connected to Phase B 204. A secondary winding 214 has three outputs, a first output 216, a second output, or a center tap, 218, and a third output 220, which are connected to a line-a 222, a neutral line 224, and a line-b 226, respectively. The transformer 200 in this example is a step-down transformer that reduces the voltage of the powered lines, in this case, Phases B 204 and C 206, from 2400 V to 120 V between the line-a 222 and the neutral 224 and between the line-b 226 and the neutral 224, and to 240 V between the line-a 222 and the line-b 226.

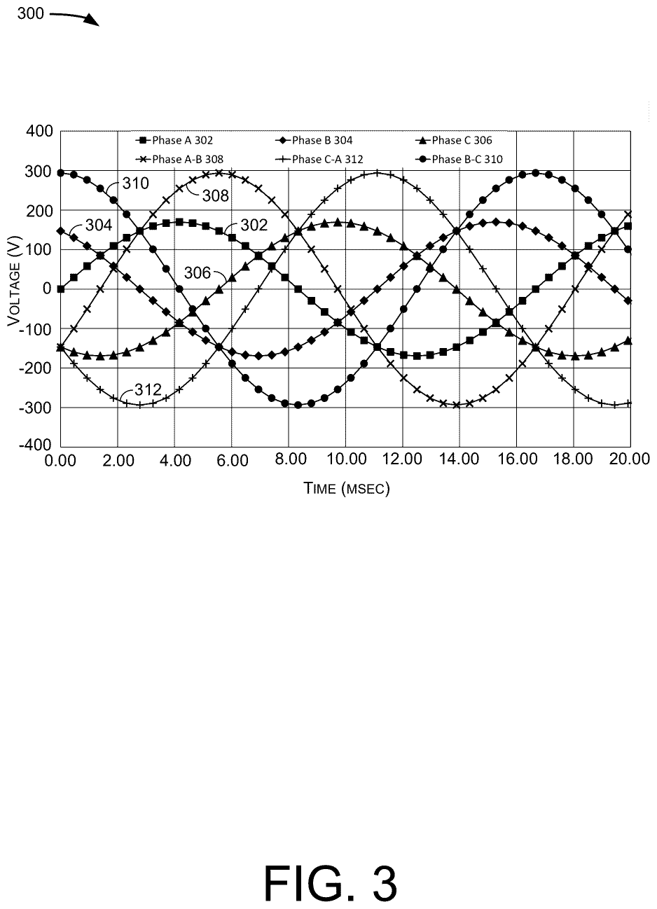

FIG. 3 illustrates an example set of voltage graphs 300 for various phases. In this example, Phase A 302 is set as a reference, Phase B 304 is 120° ahead of Phase A 302, and Phase C 306 is 240° ahead of Phase A 302. Each phase has a voltage of 120 V_{RMS} and a frequency of 60 Hz. Phase A-B 308, Phase B-C 310, and Phase C-A 312 are also shown. As shown, depending on the phase, the voltage behaves differently in magnitude over time. Poor phase balancing, such as overloading one phase, overloading equipment connected to a phase, or connecting to an incorrect phase, may cause operational inefficiency and equipment overheating, for example, increase in early equipment failure, delays in power outage response/management, and safety hazard.

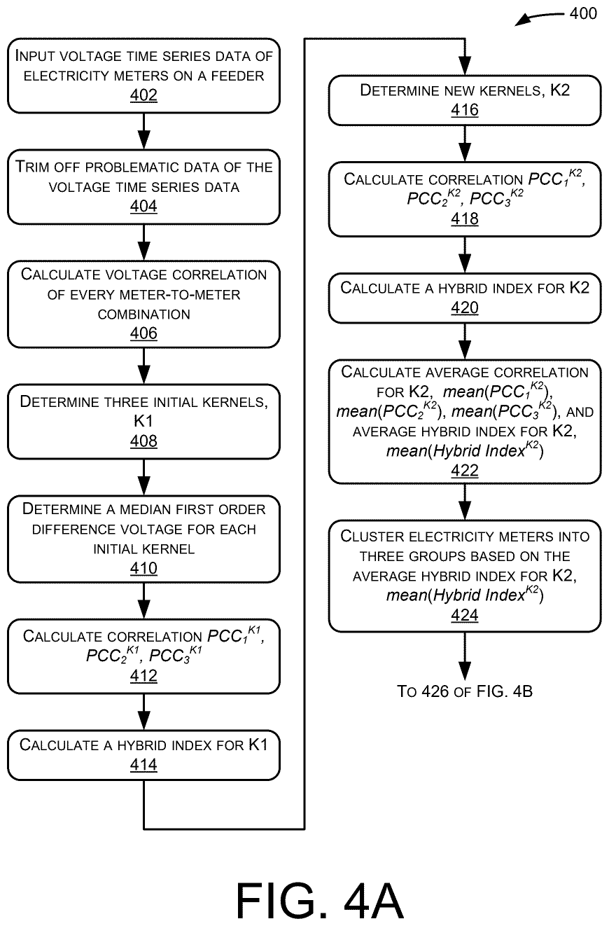

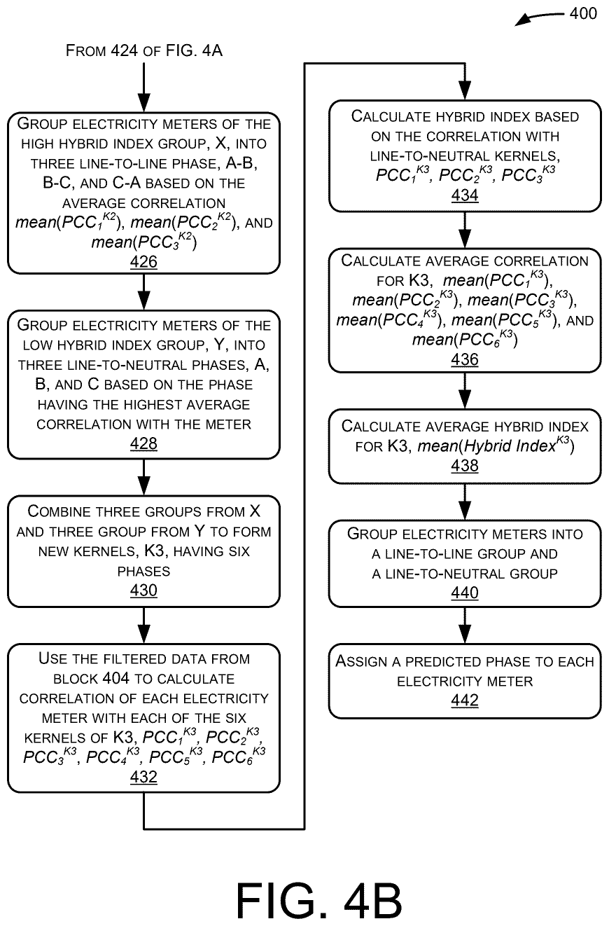

FIGS. 4A and 4B illustrate an example process 400 of a phase identification model for identifying a phase at an electricity meter level.

At block 402, voltage time series data collected from every electricity meter on a feeder is entered. A feeder is a power line consisting of individual powered lines with phases A, B, and C servicing a plurality of premises connected via electricity meters. The distinct powered lines are presumed to experience different fluctuations in RMS voltage as a result of differing loads. Those fluctuations are expected to be seen by all electricity meters connected to that line, and voltage readings on the same phase of the feeder are expected to be highly correlated compared to voltage readings on other phases. Accordingly, voltage readings collected from each electricity meter on the feeder over a preselected collection time period, such as from Jan. 1, 2020 to Dec. 31, 2020, may be entered as the voltage time series data. The voltage readings may be taken at a preselected interval, such as every five minutes with accuracy of ±0.15 V. With smart electricity meters in advanced metering infrastructure (AMI) having automated meter reading (AMR), the voltage time series data may be automatically transmitted from each electricity meter to, and collected by, a central office of the utility service provider or a third party. Additionally, an existing meter-phase connectivity record, which is the current record of information regarding each meter's connection to phase connections, may also be entered. As discussed above, the existing meter-phase connectivity record may not be up to date due to, for example, when linemen move a customer's electricity meter from one phase to another to better balance the load, but fail to record their actions and update the phase information of the customer's meter.

At block 404, the voltage time series data of each electricity meter for a preselected analysis period of the preselected collection time period, such as each month over Jan. 1, 2020 to Dec. 31, 2020, is filtered to omit problematic data. For example, expected average voltages (RMS) may be 120 V, 208 V, 240 V, 277 V, and 480 V for the meters connected to the feeder, then values that are more than ±5% out of the expected average voltages may be omitted. Frozen periods, identified as extended periods of time with constant voltage on a given meter, may be omitted. Jump outliers, identified as large interval-to-interval voltage changes outside of a preselected threshold, may be omitted. Electricity meters with insufficient amount of data over the collection time period may be omitted. Electricity meters having location information inconsistent with actual geographical locations of the electricity meters may be omitted, or the location information may be corrected and the voltage time series data of those electricity meters with the corrected location information may be used.

At block 406, voltage correlation of every meter-to-meter combination is calculated. In one example, the voltage correlation may be calculated using Pearson correlation coefficient (PCC) to determine the correlation between voltage at meter A and voltage at meter B, that is, how a change in voltage at meter A affects a change in voltage at meter B. Pearson correlation coefficient, ρ, has a value between −1 and 1, and is given by, for the correlation between X and Y:

$${ρ}_{X , Y} = \frac{cov ( X , Y )}{{σ}_{X} {σ}_{Y}} ,$$

where:
cov is the covariance,
σ_{X} is the standard deviation of X, and
σ_{Y} is the standard deviation of Y.
PCC may be calculated for every meter-to-meter pairing, and the results may be stored in a matrix.

At block 408, three initial kernels, K1 containing most of the electricity meters for Phases A, B, and C, is determined. For the process of block 408, an agglomerative cluster loop or method may be utilized to determine the three initial kernels. Examples of the agglomerative cluster method include analyses based on a single-linkage distance, Ward linkage distance, dendrogram step-through, and the like. Additionally, or alternatively, a Gaussian mixture model may be utilized to perform the clustering.

At block 410, a median first order difference voltage for each preselected interval is determined for each of the initial kernels. Correlation,

$${PCC}_{1}^{K 1} , {PCC}_{2}^{K 1} , and {PCC}_{3}^{K 1} ,$$

are calculated at block 412. At block 414, a hybrid index for the three initial kernels may be calculated based on a median of the correlations,

$${PCC}_{1}^{K 1} , {PCC}_{2}^{K 1} , and {PCC}_{3}^{K 1} ,$$

The hybrid index may be defined as the ratio of the second highest (median) correlation to the highest correlation,

$$Hybrid {Index}^{K 1} = \frac{median ( {PCC}_{1}^{K 1} , {PCC}_{2}^{K 1} , {PCC}_{3}^{K 1} , )}{max ( {PCC}_{1}^{K 1} , {PCC}_{2}^{K 1} , {PCC}_{3}^{K 1} , )} .$$

Alternatively, the hybrid index may also be defined, or calculated as:

$${alt}_{Hybrid} {Index}^{K 1} = {\{ \frac{{[ - {PCC}_{1}^{K 1} + {PCC}_{2}^{K 1} ]}^{2}}{2} + \frac{{[ {PCC}_{1}^{K 1} + {PCC}_{2}^{K 1} - 2 * {PCC}_{3}^{K 1} ]}^{2}}{6} \}}^{\frac{1}{2}}$$

The hybrid index is used to separate out the line-to-line connections from the line-to-neutral connections as described later in more detail. Based on the Hybrid Index^{K1}, new kernels for each phase, K2, are determined at block 416. The correlation between each of the electricity meters and the new kernels,

$${PCC}_{1}^{K 2} , {PCC}_{2}^{K 2} , and {PCC}_{3}^{K 2} ,$$

are calculated at block 418, and Hybrid Index^{K2} is calculated at block 420.

At block 422, for each preselected analysis period, average correlation with each phase for the new kernels, K2,

$$mean ( {PCC}_{1}^{K 2} ) , mean ( {PCC}_{2}^{K 2} ) , and mean ( {PCC}_{3}^{K 2} ) ,$$

and average hybrid index for K2, mean(Hybrid Index^{K2}), are calculated. The electricity meters are then clustered into three groups based on the average hybrid index for K2, mean(Hybrid Index^{K2}) at block 424. The three groups include a group with a high hybrid index, which is considered to be the line-to-line phase group, a group with low hybrid index, which is considered to be line-to-neutral phase group, and a group with in-between hybrid index values is used as a band separating the high and low hybrid index groups. At block 426, the electricity meters of the high hybrid index group, X, are grouped into three line-to-line phases, A-B, B-C, and C-A, based on the average correlation,

$$mean ( {PCC}_{1}^{K 2} ) , mean ( {PCC}_{2}^{K 2} ) , and mean ( {PCC}_{3}^{K 2} ) .$$

For the clustering processes of blocks 424 and 426, the agglomerative cluster method as described above may be utilized.

At block 428, the electricity meters of the low hybrid index group, Y, are grouped into three line-to-neutral phases, A, B, and C, based on the phase having the highest average correlation,

$$mean ( {PCC}_{1}^{K 2} ) , mean ( {PCC}_{2}^{K 2} ) , and mean ( {PCC}_{3}^{K 2} )$$

with the meter. The three line-to-line groups of electricity meters and the three line-to-neutral groups of electricity meters are combined as new kernels, K3, having six phases, A, B, C, A-B, B-C, and C-A, at block 430.

At block 432, the filtered data from block 404 is used to calculate correlation of each electricity meter with each of the six kernels of K3,

$${PCC}_{1}^{K 3} , {PCC}_{2}^{K 3} , {PCC}_{3}^{K 3} , {PCC}_{4}^{K 3} , {PCC}_{5}^{K 3} , and {PCC}_{6}^{K 3} ,$$

and hybrid index based on the correlation with line-to-neutral kernels,

$${PCC}_{1}^{K 3} , {PCC}_{2}^{K 3} , and {PCC}_{3}^{K 3} ,$$

is calculated at block 434. At block 436, average correlation with each of six phases are calculated as

$$mean ( {PCC}_{i}^{K 3} ) , for i = 1 , 2 , 3 , 4 , 5 , 6 ,$$

where i represents each of the six phases, A, B, C, A-B, B-C, and C-A. At block 438, an average hybrid index, mean(Hybrid Index^{K3}) is calculated. The electricity meters are grouped into two groups, a line-to-line group and a line-to-neutral group at block 440. The agglomerative cluster method described above may be utilized to group electricity meters with a high average hybrid index into the line-to-line group and electricity meters with a low average hybrid index into the line-to-neutral group. A predicted phase is assigned to each meter based on the highest correlation at block 442. For the line-to-line group, the predicted phase is the one with a highest correlation in

$$mean ( {PCC}_{i}^{K 3} ) , for i = 4 , 5 , 6 ,$$

and for the line-to-neutral group, the predicted phase is the one with a highest correlation in

$$mean ( {PCC}_{i}^{K 3} ) , for i = 1 , 2 , 3.$$

The predicted phase ay then be output for comparison with the existing meter-phase connectivity record.

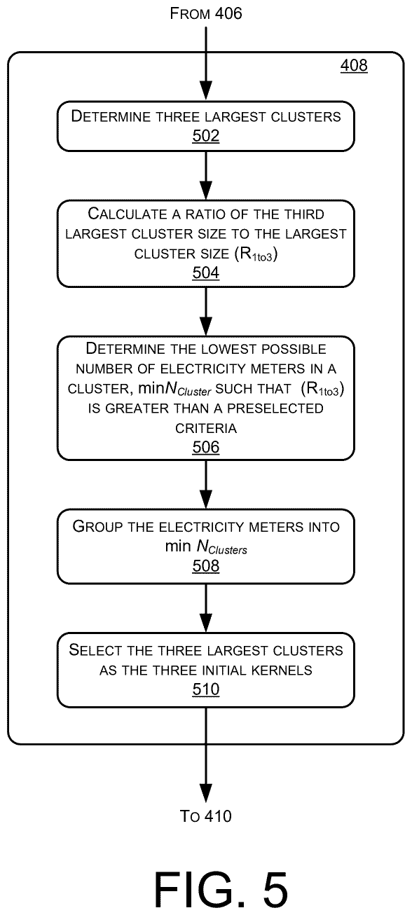

FIG. 5 illustrates an example detail process of block 408 of FIG. 4. At block 502, three largest clusters of electricity meters are determined. For all possible number of clusters from three to the number of meters in the sample, the largest three clusters, from large to small, L1, L2, and L3 are determined. At block 504, a ratio of the third largest cluster size to the largest cluster size,

$${R}_{1 t o 3} = \frac{{size}_{L 3}}{{size}_{L 1}} ,$$

is calculated. At block 506, the lowest possible number of clusters, min N_{Clusters}, such that R₁ₜₒ₃ is greater than a preselected criteria, is determined, which ensures that the three initial kernels obtained are not too imbalanced. For example, for the preselected criteria of 0.5, the largest cluster is no larger than twice the size of the smallest cluster. At block 508, the agglomerative cluster method may be utilized to group the electricity meters into the min N_{Clusters} calculated in block 506. At block 510, the three largest clusters are selected as the three initial kernels, and the process proceeds to block 410.

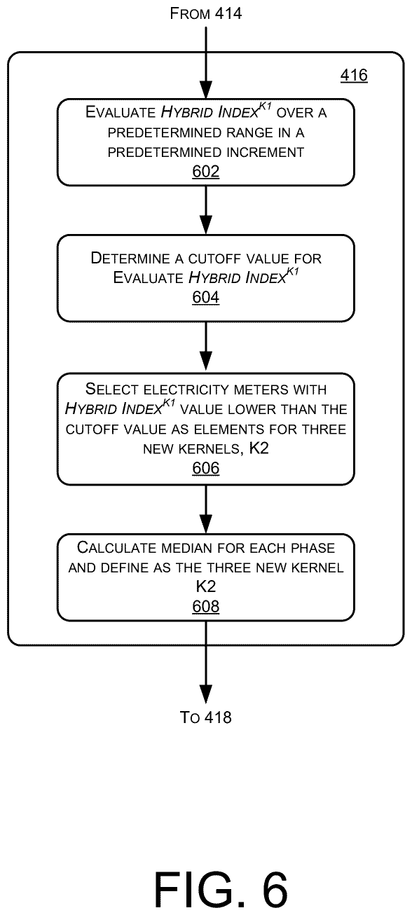

FIG. 6 illustrates an example detail process of block 416 of FIG. 4. At block 602, a predetermined range, for example from 0.75 to 0.85, of Hybrid Index^{K1} is evaluated in a predetermined increment, for example, 0.01, and a cutoff value of Hybrid Index^{K1} is determined at block 604. The cutoff value of Hybrid Index^{K1} may be defined as a value of Hybrid Index^{K1} below which there exist a first sufficient number of electricity meters for each phase and, above which there exist a second sufficient number of electricity meters, where the first and second sufficient numbers may be preselected. At block 606, electricity meters with Hybrid Index^{K1} value lower than the cutoff value are selected as the elements for three new kernels, K2, and median of each phase is calculated and defined as three new kernels, K2, at block 608. The process then proceeds to block 418.

Accordingly, a method, or a process, described above with reference to FIGS. 4-6, may include: calculating voltage correlations of meter-to-meter combinations of a plurality of electricity meters based on voltage time series data collected over a preselected collection time period, each electricity meter of the plurality of electricity meters connected to one of six phases comprising three line-to-neutral phases and three line-to-line phases; clustering the plurality of electricity meters into three initial kernels representing the three line-to-neutral phases based on voltage correlations; for each of the three initial kernels, calculating correlation values with each electricity meter of the plurality of electricity meters; determining three new kernels based on the correlation values; clustering the plurality of electricity meters into three groups based on a hybrid index for the three new kernels calculated based on average correlation values associated with each electricity meter; forming six new kernels of electricity meters representing the six phases based on the average correlation values associated with each electricity meter; and assigning a predicted phase to an electricity meter of the plurality of electricity meters based on corresponding correlation values of the electricity meter with each of the six new kernels based on the voltage time series data.

The voltage time series data collected over the preselected collection time period described above may include at least one of voltage time series data: 1) collected by the plurality of electricity meters, 2) stored by the plurality of electricity meters, 3) transmitted by the plurality of electricity meters to, and stored by, a central office of a utility service provider, or 4) obtained from the central office. The voltage time series data may additionally, or alternatively, may include a preselected analysis period of voltage data associated with an electricity meter of the plurality of electricity meters taken over a preselected collection time period at a preselected interval.

Prior to calculating the voltage correlations of meter-to-meter combinations, the method may further include omitting problematic data of the voltage time series data, wherein the problematic data may include: 1) voltage values deviating more than a preselected value from an expected average value, 2) constant voltage over longer than a predetermined period, 3) missing data over more than a preselected number of preselected intervals, and 4) data from an electricity meter having location information inconsistent with an actual geographical location of the electricity meter.

Clustering the plurality of electricity meters into the three initial kernels of the method above may include: determining three largest clusters of electricity meters for all clusters having at least three electricity meters and up to all electricity meters of the plurality of electricity meters; determining a ratio of a third largest cluster size of the three largest clusters to a largest cluster size of the three largest clusters; determining a lowest number of clusters, such that the ratio is greater than a preselected criteria; grouping the plurality of electricity meters into the lowest number of clusters; and selecting three largest clusters as the three initial kernels. Determining the three new kernels based on the correlation values of the method above may include: evaluating hybrid index values of a predetermined range for the three initial kernels, a hybrid index value calculated as a ratio of a median correlation value of the three initial kernels to a maximum correlation value of the three initial kernels; determining a cutoff value of the hybrid index below which there are more than a first preselected number of electricity meters for each phase and above which there are more than a second preselected number of electricity meters; and selecting electricity meters with hybrid index values below the cutoff value as elements for the three new kernels.

Clustering the plurality of electricity meters into three groups of the method above may include: clustering a group of electricity meters with a high hybrid index as a line-to-line phase group, clustering electricity meters with a low hybrid index as a line-to-neutral phase group, and clustering electricity meters with in-between hybrid index values as a band separating the high and low hybrid index groups. Forming the six new kernels of electricity meters representing the six phases may include: grouping electricity meters having the high hybrid index into three line-to-line phase groups based on average correlations of a phase with each electricity meter; grouping electricity meters having the low hybrid index into three line-to-neutral phase groups based on highest average correlations of a phase with each electricity meter; and forming the six new kernels of electricity meters by combining the three line-to-line phase groups and the three line-to-neutral phase groups.

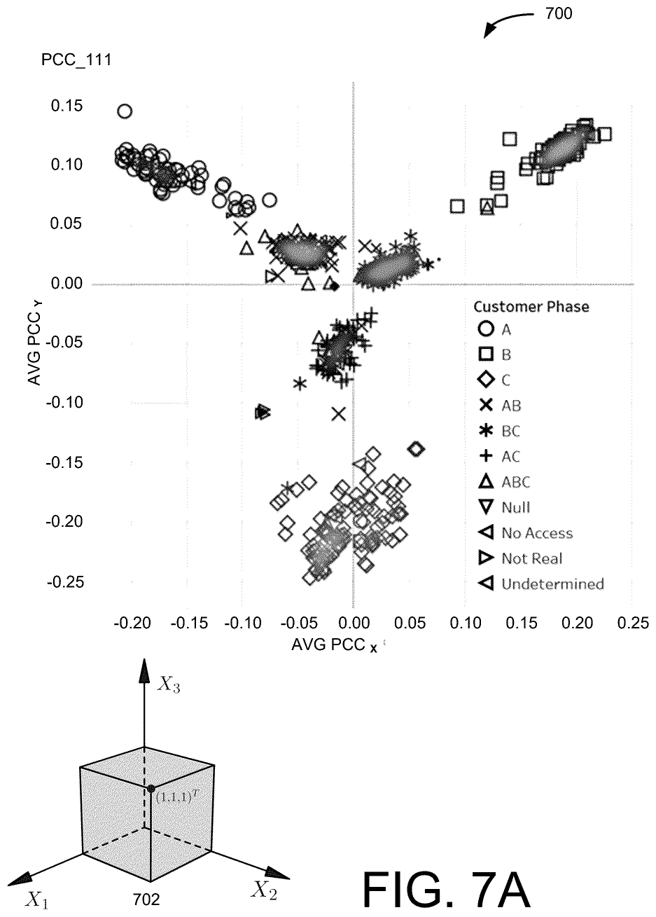

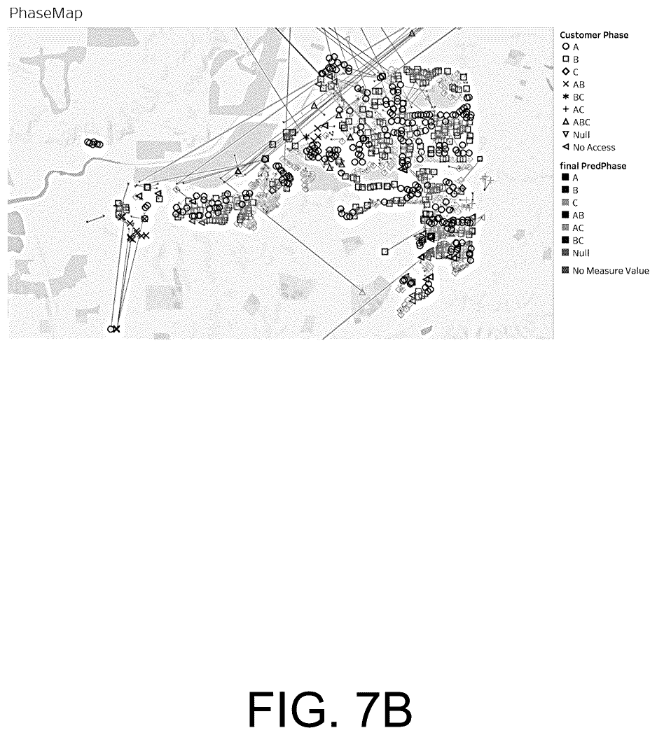

FIG. 7A illustrates an example display 700 of the clusters of electricity meters. Clusters of electricity meters may be displayed when each meter is plotted in 3D coordinates based on its correlation to phases A, B and C. The display 700 is a 2D view of the 3D plot viewed from the point (1,1,1) facing the origin (0,0,0) as shown by a graphical representation 702. FIG. 7B illustrates an example display 704 of phases of the electricity meters of FIG. 7A plotted over the locations of the electricity meters on a map.

In an ideal situation, when the algorithm successfully separates the meters into right clusters and no voltage regulations are affecting the voltage across all three phases for a subset of the feeder, each of the three phase correlation lines, representing the average correlation with each of the phases A, B, and C, would be near 120° apart from the adjacent phase correlation line (a separation angle of 120°). However, where the phases are not evenly distributed, the angle between the adjacent phase correlation lines deviates from 120°. To determine an amount of deviation, or correctness of the predicted phases of the cluster of electricity meters, indices described below are utilized to indicate whether the phase identification model, described above with reference to FIGS. 4-7, works at a circuit level, and if the phase identification model is indicated to work at the circuit level, then to determine reliability of the phase prediction for a specific electricity meter.

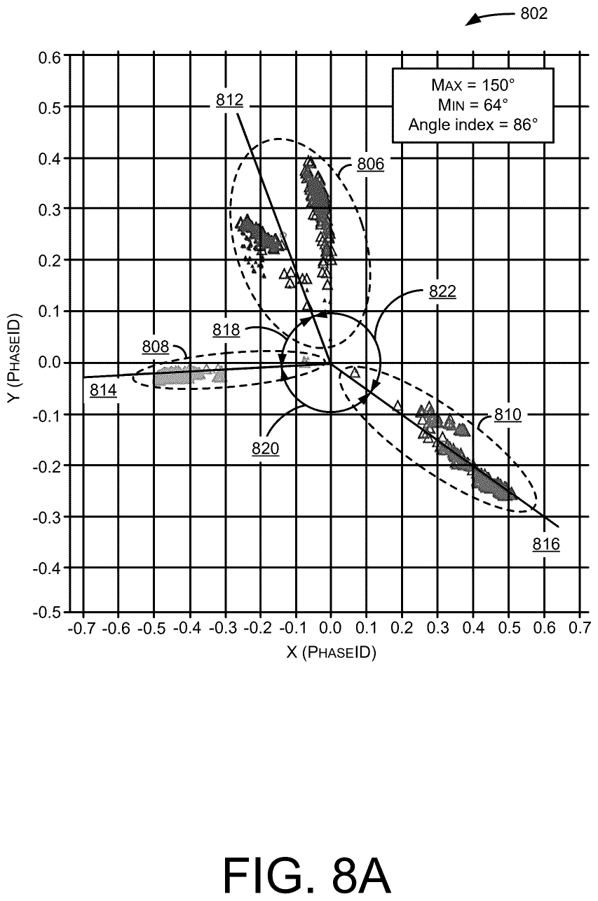

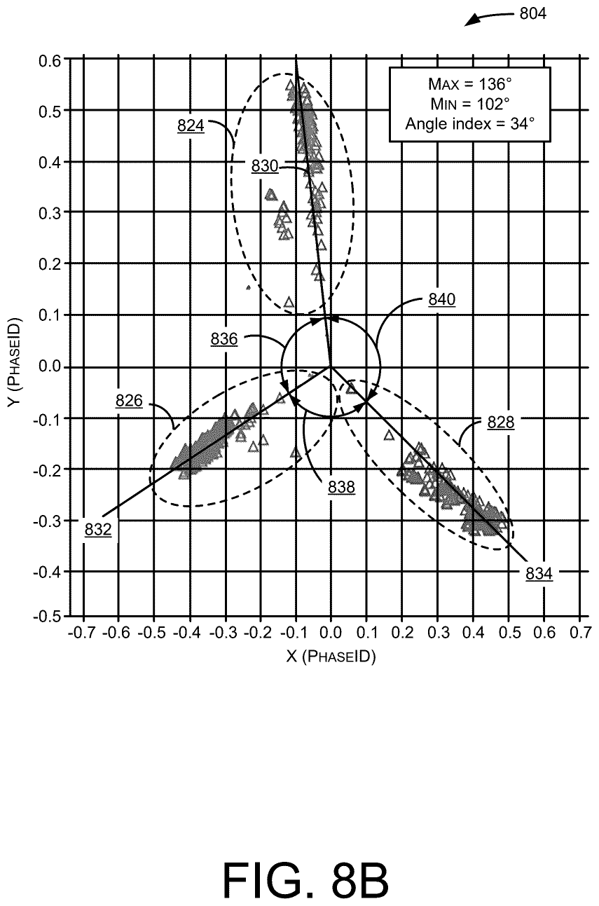

FIGS. 8A and 8B illustrate example phase correlation plots 802 and 804 having non-120° separation angles between adjacent phase lines. In FIG. 8A, correlations of a first plurality of electricity meters associated with the phases A, B, and C are shown as a first cluster 806, a second cluster 808, and a third cluster 810, respectively. First, second, and third phase correlation lines 812, 814, and 816, pass through the average correlation point and the origin for the first, second, and third clusters 806, 808, and 810, respectively. In this example, a separation angle 818 between the first and the second phase correlation lines 812 and 814 is 64°, a separation angle 820 between the second and the third phase correlation lines 814 and 816 is 146°, and a separation angle 822 between the third and the first phase correlation lines 816 and 812 is 150°. An angle index may be defined as a difference between the maximum and the minimum separation angles, and may provide an indication of how well the phase identification model has performed or predicted. For example, when the three clusters 806, 808, and 810 are evenly distributed, the angle index is 0. In other words, a smaller angle index indicates a better prediction by the phase identification model. In this example, the angle index is 86°, that is 150° (separation angle 822)−64° (separation angle 818). Additionally, or alternatively, the angle index may be defined as a ratio of the minimum separation angle and the maximum separation angle. For this angle index, a ratio of a value closer to 1 indicates a better prediction by the phase identification model. The angle index, in this example, may be determined as the ratio of the separation angle 818 (the minimum separation angle) and the separation angle 822 (the maximum separation angle) of 64°/150°=0.427.

In FIG. 8B, correlations of a second plurality of electricity meters associated with the phases A, B, and C are shown as a first cluster 824, a second cluster 826, and a third cluster 828, respectively. First, second, and third phase correlation lines 830, 832, and 834, pass through the average correlation point and the origin for the first, second, and third clusters 824, 826, and 828, respectively. In this example, a separation angle 836 between the first and the second phase correlation lines 830 and 832 is 122°, a separation angle 838 between the second and the third phase correlation lines 832 and 834 is 102°, and a separation angle 840 between the third and the first phase correlation lines 834 and 830 is 136°. The angle index is then 34°, that is 136° (separation angle 840)−102° (separation angle 838). The angle index, defined as the ratio of the minimum separation angle and the maximum separation angle, for this example, may be determined as the ratio of the separation angle 838 (the minimum separation angle) and the separation angle 840 (the maximum separation angle) of 102°/136°=0.75. Therefore, based on the angle indices of the phase correlation plots 802 and 804, the phase distributions of the second plurality of electricity meters of the plot 804 represent better predictions by the phase identification model over the phase distributions of the first plurality of electricity meters of the phase correlation plot 802.

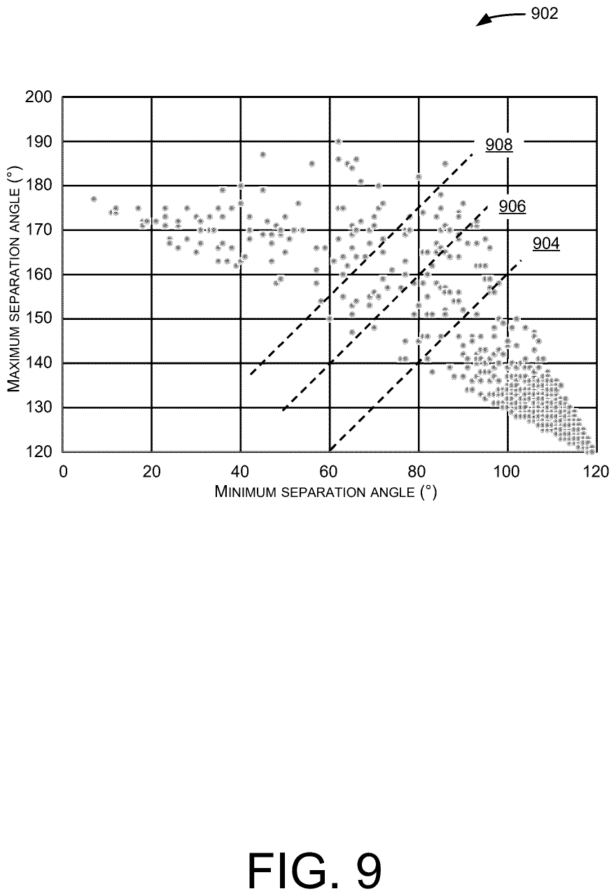

FIG. 9 illustrates an example plot 902 of minimum separation angle vs. maximum separation angle for analyzing the angle index. As described above with reference to FIGS. 8A and 8B, the angle index is defined as the difference between the maximum separation angle and the minimum separation angle, where a lower angle index indicates a better phase identification model. When viewed in the plot of the minimum separation angle vs. maximum separation angle, a line having a slope of positive one represents equal angle index value. For example, any point on a first angle index line 904 has the angle index of 60°, any point on a second angle index line 906 has the angle index of 80°, and any point on a first angle index line 904 has the angle index of 95°. As the phase identification model improves towards the coordinate (120, 120), the plot 902 may visually assist in determining a cutoff point for the angle index, or a threshold angle index, over which the phase identification model may be considered invalid. In this example, a majority of the angle indices are shown to be less than about 60°, as indicated by the first angle index line 904.

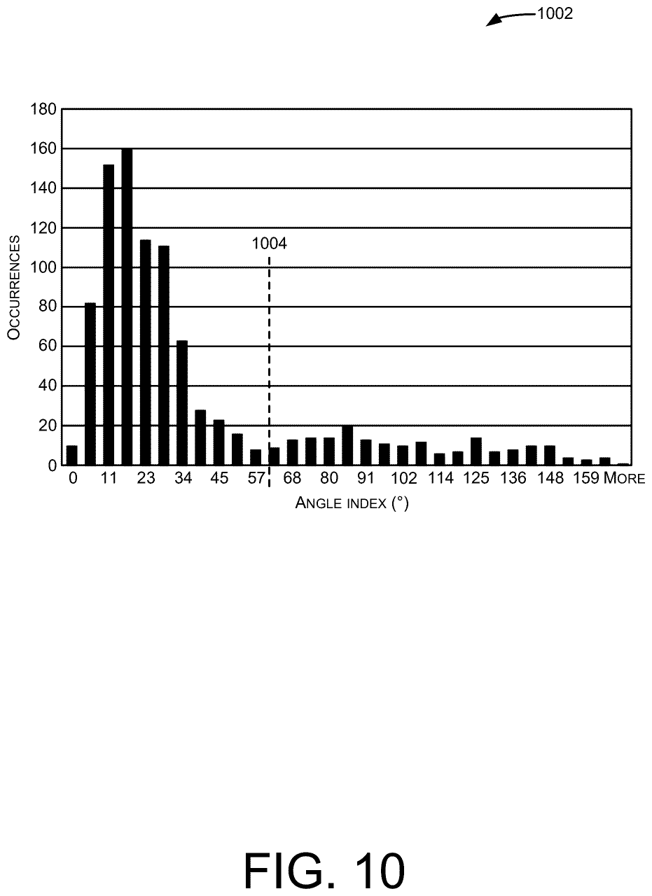

FIG. 10 illustrates the same data used in FIG. 9 expressed as an example histogram 1002 of angle indices, which visually indicates a cutoff point, or a threshold angle index, separating between models with good fits and bad fits. In this example, the threshold angle index, separating a majority of occurrences and a tail of occurrences, is about 60° as shown with a dotted line 1004.

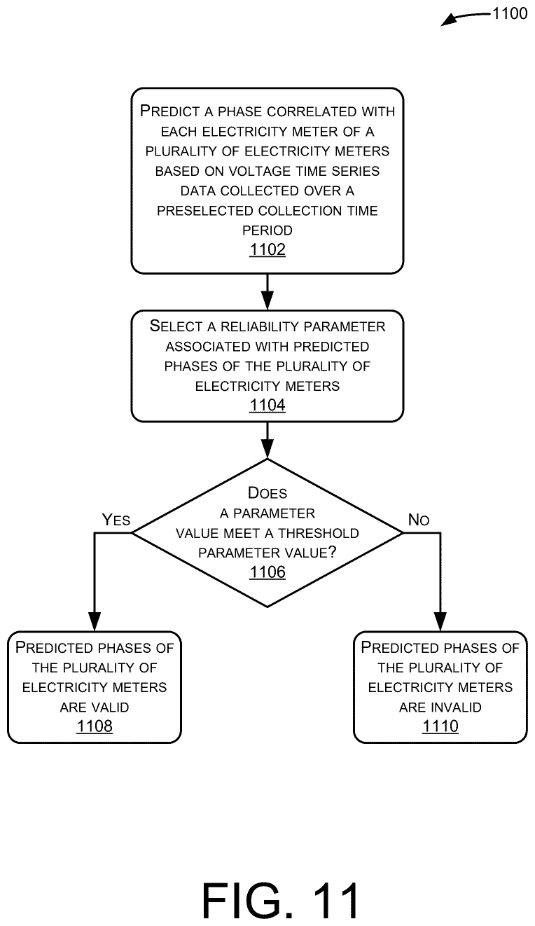

FIG. 11 illustrates an example process 1100 for determining validity of phase assignments by the phase identification model described above with reference to FIGS. 4-6. At block 1102, a phase correlated with each electricity meter of a plurality of electricity meters may be predicted, or identified, based on voltage time series data collected over a preselected collection time period, for example, based on the phase identification model discussed above with reference to FIGS. 4-6. The phase predicted may be one of a first phase, such as Phase A, a second phase, such as Phase B, or a third phase, such as Phase C. At block 1104, a reliability parameter associated with predicted phases of the plurality of electricity meters may be selected, and whether a parameter value associated with the reliability parameter meets a threshold parameter value may be determined at block 1106. Based on determining that the parameter value meets the threshold parameter value at block 1106 (“YES” branch), the predicted phases of the plurality of electricity meters are determined to be valid at block 1108, and based on determining that the parameter value fails to meet the threshold parameter value at block 1106 (“NO” branch), the predicted phases of the plurality of electricity meters are determined to be invalid at block 1110. Depending on the selected reliability parameter, the parameter value of the selected reliability parameter may be determined to meet the threshold parameter value when the parameter value is 1) greater than the threshold parameter value or 2) less than the threshold parameter value, as described below.

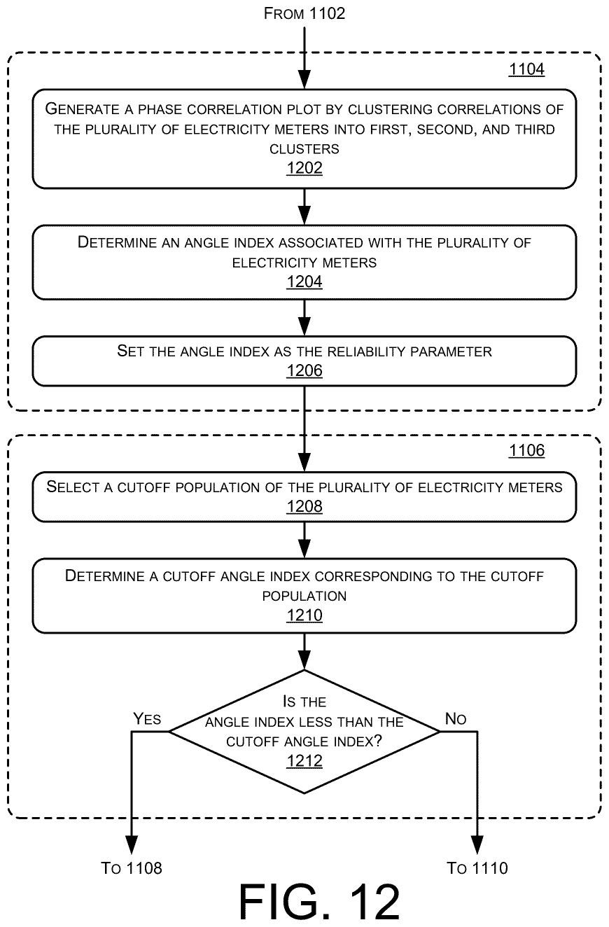

FIG. 12 illustrates first example detail processes of blocks 1104 and 1106 of FIG. 11. At block 1202, a phase correlation plot, such as plots 802 and 804, may be generated by clustering the plurality of electricity meters into a first cluster, such as the first clusters 806 and 824, a second cluster, such as the second clusters 808 and 826, and a third cluster, such as the third clusters 810 and 828, based on each phase corelated to the plurality of electricity meters. At block 1204, three phase correlation lines may be determined. The three phase correlation lines include a first phase correlation line, such as the first phase correlation lines 812 and 830 associated with the first clusters 806 and 824, a second phase correlation line, such as the second phase correlation lines 814 and 832 associated with the second clusters 808 and 826, and a third phase correlation, such as the third phase correlation lines 816 and 834 associated with the first clusters 810 and 828 described above with reference to FIGS. 8A and 8B. At block 1204, an angle index associated with the plurality of electricity meters may be determined. As described above with reference to FIGS. 8A and 8B, the angle index may be defined as a difference between a maximum separation angle, such as the angles 822 and 840, and a minimum separation angle, such as the angles 818 and 834, where a separation angle is an angle between adjacent phase correlation lines on the phase correlation plot, such as the angle 822 between the first phase correlation line 812 and the third phase correlation line 816. The angle index may then be set as the reliability parameter at block 1206.

At block 1208, a cutoff population of the plurality of electricity meters may be selected, and a cutoff angle index corresponding to the cutoff population may be determined at block 1210 as the threshold parameter value. For example, as discussed above with reference to FIGS. 9 and 10, the cutoff population, such as 90% of the population may be selected, and the cutoff angle index corresponding to 90% of the population, such as 60° as indicated by the first angle index line 904 and the dotted line 1004, may be determined. That is, a model is considered to be valid, if 90% of the plurality of electricity meters has the angle index less than the cutoff angle index of 60°. At block 1212, whether the angle index is less than the cutoff angle index is determined. If the angle index is determined to be less than the cutoff angle index (“YES” branch), the process proceeds to block 1108, and if the angle index is not determined to be less than the cutoff angle index (“NO” branch), the process proceeds to block 1110.

Additionally, or alternatively, as described above with reference to FIGS. 8A and 8B, the angle index may be expressed as a ratio of the minimum separation angle and the maximum separation angle, and a value of the angle index closer to 1 indicates a better prediction by the phase identification model. For example, the cutoff population of 90% may be selected, which may correspond to the cutoff angle index of 0.5. Then, at block 1212, whether the angle index is greater than the cutoff angle index, i.e., 0.5, is determined. If the angle index is determined to be greater than the cutoff angle index (“YES” branch), the process proceeds to block 1108, and if the angle index is not determined to be greater than the cutoff angle index (“NO” branch), the process proceeds to block 1110.

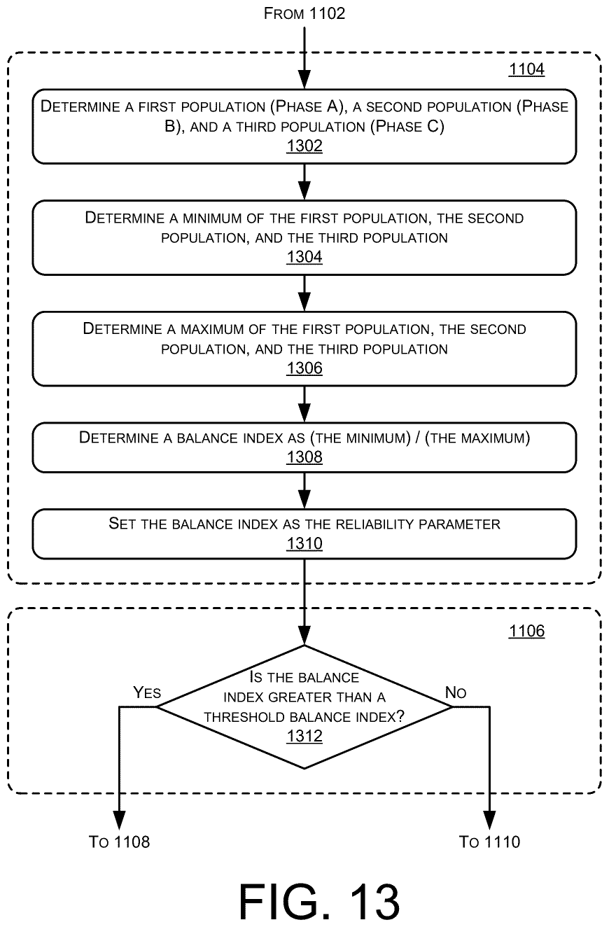

FIG. 13 illustrates second example detail processes of blocks 1104 and 1106 of FIG. 11. To determine whether the predicted number of electricity meters belonging to each phase is correct, a balance index, defined as a ratio of the predicted number, or population, of electricity meters of the smallest phase to the predicted number, or population, of electricity meters of the largest phase, may be calculated. For example, if the feeder 108 is balanced in the phase assignments and the prediction is correct, then the number of electricity meters belonging to each of the three phases, A, B, and C, should be similar, providing the balance index close to 1. However, if the balance index is determined to be less than a preselected threshold index, then the prediction may be considered to be incorrect, i.e., the predicted distribution of electricity meters is likely incorrect. Therefore, an unreasonable balance index indicates that the assumption that “the prediction is correct” is incorrect. To determine, or calculate, the balance index, the predicted number of electricity meters belonging to each phase is first summarized. The balance index is then calculated as the ratio of the predicted number of electricity meters of the smallest phase to the predicted number of electricity meters of the largest phase as shown below.

$$BalanceIndex = \frac{min ( {Size}_{A} , {Size}_{B} , {Size}_{C} )}{max ( {Size}_{A} , {Size}_{B} , {Size}_{C} )} ,$$

where:
Size_{A} is the predicted number, or population, of electricity meters belonging to Phase A,
Size_{B} is the predicted number, or population, of electricity meters belonging to Phase B, and
Size_{C} is the predicted number, or population, of electricity meters belonging to Phase C.

At block 1302, a first population of electricity meters of the plurality of electricity meters predicted as belonging to the first phase, such as Phase A, a second population number of electricity meters of the plurality of electricity meters predicted as belonging to the second phase, such as Phase B, and a population number of electricity meters of the plurality of electricity meters predicted as belonging to the third phase, such as Phase C, may be determined. At block 1304, a minimum of the first population, the second population, and the third population may be determined, and a maximum of the first population, the second population, and the third population may be determined at block 1306. At block 1308, a balance index, as a ratio of the minimum size and the maximum size as described above, may be determined, and the balance index may be set as the reliability parameter at block 1310. At block 1312, whether the balance index is greater than a threshold balance index may be determined. If the balance index is determined to be greater than the threshold balance index (“YES” branch), the process proceeds to block 1108, and if the balance index is not determined to be greater than the threshold balance index (“NO” branch), the process proceeds to block 1110. As discussed above, because an indication of the phase identification model performing correctly improves as the balance index approaches 1, the threshold balance index may be selected to be close to 1, for example, from 0.8 to 1.0 depending on a desired level of the phase identification model performance.

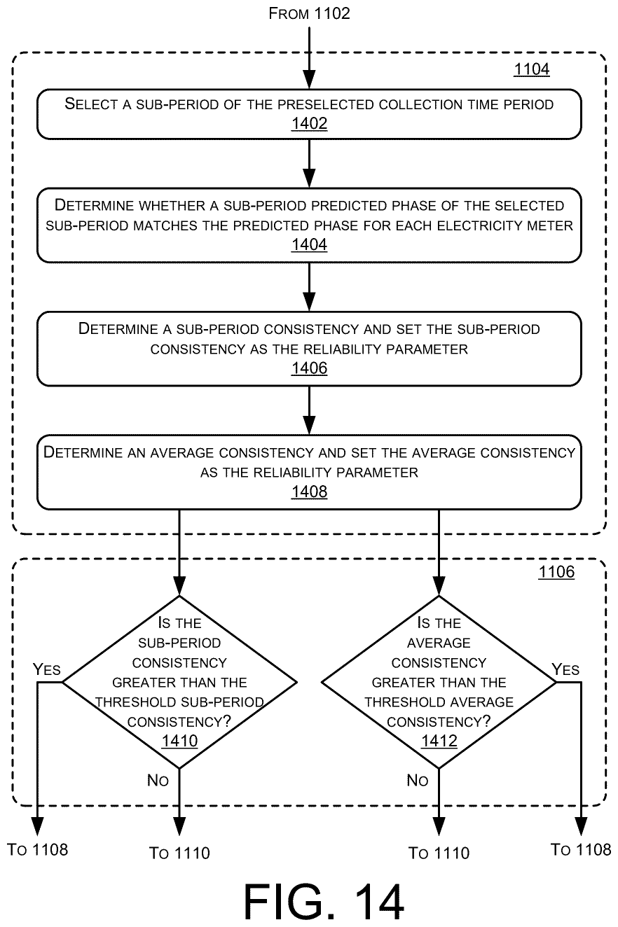

FIG. 14 illustrates third example detail processes of blocks 1104 and 1106 of FIG. 11. The phase identification model, or algorithm, described above with reference to FIGS. 4-7, utilizes multiple sub-period data and combines sub-period predictions to derive a final prediction. By comparing sub-period predictions to the final prediction, consistency of the sub-period predictions may be determined. Repeatedly having a similar prediction, i.e., higher or better consistency approaching 1, provides confidence with the results that the phase identification model is working properly. To determine consistency, a predicted phase, by the phase identification model, for each electricity meter for a sub-period (sub-period predicted phase) may be compared with a final overall prediction for the electricity meter. The preselected collection time period may include a plurality of sub-periods, such as a week, a month, or any time period used for the phase identification model, and the sub-period predicted phase may be determined as part of the phase identification model. A number, or population, of the electricity meters having the sub-period predicted phase matching corresponding final overall prediction may be added up and a percentage of electricity meters having the sub-period predicted phase matching the corresponding final overall predicted phase may be calculated. A sub-period consistency, consistencyₜ, may be determined and expressed in percentage as shown below.

$${Consistency}_{t} = \frac{{\sum }_{i} iif ( {Pred}_{i , t} = {FinalPred}_{i} , 1 , 0 )}{I} \times 100 ,$$

where:
t is a sub-period,
I is the total number of electricity meters,
i indicates i-th electricity meter of the electricity meters,
Pred_{i, t} is a phase prediction for the i-th electricity meter for the sub-period t,
FinalPredᵢ is a final phase prediction for the i-th electricity meter.

An overall consistency may then be calculated by averaging the sub-period consistencies over the total number of sub-periods, T, as shown below.

$$Consistency = \frac{{\sum }_{t} {Consistency}_{t}}{T} .$$

At block 1402, a sub-period of the preselected collection time period may be selected. As discussed above, the preselected collection time period may include a plurality of sub-periods, such as a week, a month, or any time period used for the phase identification model. At block 1404, whether a sub-period predicted phase of the selected sub-period associated with the predicted phase matches the predicted phase may be determined for each electricity meter of the plurality of electricity meters. At block 1406, a sub-period consistency may be determined as ratio of a sub-period phase matching population of electricity meters, that is, a population of electricity meters having sub-period predicted phases matching the corresponding predicted phases, to the number of electricity meters in the plurality of electricity meters. The sub-period consistency may be set as the reliability parameter and expressed as percentage. At block 1408, an average consistency may be determined by averaging sub-period consistencies over the preselected collection time period, and the average consistency may additionally, or alternatively, be set as the reliability parameter.

At block 1410, whether the sub-period consistency is greater than a threshold sub-period consistency may be determined. If the sub-period consistency is determined to be greater than the threshold sub-period consistency (“YES” branch), the process proceeds to block 1108, and if the sub-period consistency is not determined to be greater than the threshold sub-period consistency (“NO” branch), the process proceeds to block 1110. Additionally, or alternatively, at block 1412, whether the average consistency is greater than a threshold average consistency may be determined. If the average consistency is determined to be greater than the threshold average consistency (“YES” branch), the process proceeds to block 1108, and if the average consistency is not determined to be greater than the threshold average consistency (“NO” branch), the process proceeds to block 1110.

As discussed above, because an indication of the phase identification model performing correctly improves as the sub-period consistency, or the average consistency, approaches 1, the threshold for both of the sub-period and average consistencies may be selected to be close to 1, for example, from 0.8 to 1.0 depending on a desired level of the phase identification model performance.

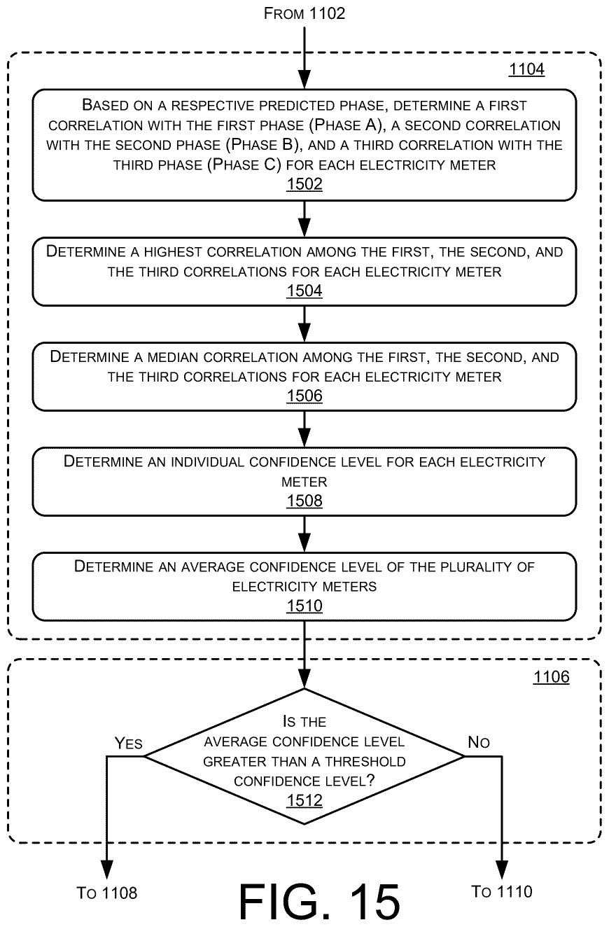

FIG. 15 illustrates fourth example detail processes of blocks 1104 and 1106 of FIG. 11. A confidence level at an electricity meter level, confidenceᵢ, or a Z score, Zᵢ, may be utilized to test how confident the prediction is, or to determine a confidence level, for each electricity meter based on successful feeder level predictions by the phase identification algorithm. For example, for each electricity meter, the phase identification model predicts the electricity meter as having, or belonging to, Phase A based on the correlation of the electricity meter with Phase A being the highest among the correlations with Phases A, B, and C. While the highest correlation, such as the correlation with Phase A in this example, being significantly higher than the second correlation would indicate the electricity meter belonging to Phase A with high confidence, the highest correlation being only slightly higher than the second highest correlation may be a result of random error in data. Confidenceᵢ, or Zᵢ, where i indicates the i-th electricity meter of/(total number) electricity meters, compares the highest correlation with the second highest correlation with results following a normal distribution, which allows statistics analysis and meaningful predictions.

After calculating correlations between electricity meters and kernels, the correlations with phases A, B, and C are denoted as r_{A}, r_{B}, and r_{C}, respectively, for the electricity meter i, and the number of observations used to determine these correlations as n_{A}, n_{B}, and n_{C}, respectively. Confidenceᵢ, or, Zᵢ, for the electricity meter i may be determined as:

$${Z}_{i} = \frac{ln \frac{( 1 + {r}_{1} ) ( 1 - {r}_{2} )}{( 1 - {r}_{1} ) ( 1 + {r}_{2} )}}{\sqrt{\frac{4}{{n}_{1} - 3} + \frac{4}{{n}_{2} - 3}}} , where : \\ {r}_{1} = max ( {r}_{A} , {r}_{B} , {r}_{C} ) , {n}_{1} = the corresponding number of observations , {r}_{2} = median ( {r}_{A} , {r}_{B} , {r}_{C} ) , and \\ {n}_{2} = the corresponding number of observations ,$$

Zᵢ follows a normal distribution when n₁ and n₂ are sufficiently large, allowing statistical analysis applicable to a normal distribution. Based on Zᵢ, an average confidence, AvgConfidence, across confidence levels for all electricity meters on a feeder or circuit may be determined as:

$$AvgConfidence = \frac{1}{I} {\sum }_{i} {Confidence}_{i} , where : \\ I = total number of electricity meters .$$

At block 1502, based at least in part on a respective predicted phase, a first correlation with the first phase, such as Phase A, a second correlation with the second phase, such as Phase B, and a third correlation with the third phase, such as Phase C, may be determined for each electricity meter of the plurality of electricity meters. At block 1504, a highest correlation among the first correlation, the second correlation, and the third correlation may be determined for each electricity meter of the plurality of electricity meters, and a median correlation among the first correlation, the second correlation, and the third correlation may be determined for each electricity meter of the plurality of electricity meters at block 1506. At block 1508, an individual confidence level based at least in part on the highest correlation, a first number of observations associated with the highest correlation, the median correlation, and a second number of observations associated with the median correlation may be determined for each electricity meter of the plurality of electricity meters as described above with reference to Confidenceᵢ, or, Zᵢ. At block 1510, an average confidence level of the plurality of electricity meters may be determined based on individual confidence levels of the plurality of electricity meters as described above with reference to AvgConfidence, and the average confidence level may be set as the reliability parameter at block 1512. At block 1514, whether the average confidence level is greater than a threshold confidence level may be determined. If the average confidence level is determined to be greater than the threshold confidence level (“YES” branch), the process proceeds to block 1108, and if the average confidence level is not determined to be greater than the threshold confidence level (“NO” branch), the process proceeds to block 1110.

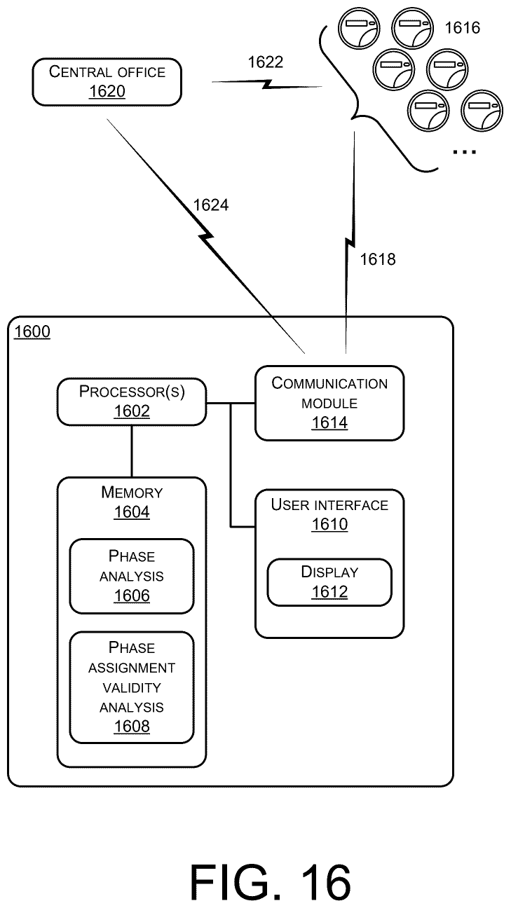

FIG. 16 illustrates an example block diagram of a system 1600 for determining validity of phase assignments by the phase identification model. The system 1600 may comprise one or more processors (processors) 1602 communicatively coupled to memory 1604. The processors 1602 may include one or more central processing units (CPUs), graphics processing units (GPUs), both CPUs and GPUs, or other processing units or components known in the art. The processors 1602 may execute computer-executable instructions stored in the memory 1604 to perform functions or operations, with one or more of components communicatively coupled to the one or more processors 1602 and the memory 1604, as described above with reference to FIGS. 4-15. For example, the memory 1604 may store a phase analysis application 1606 that is executed for analyzing and determining, or identifying, the phases associated with the plurality of electrical meters as described above with reference to FIGS. 4-7 and a phase assignment validity analysis application 1608 for determining validity of the identified phases of the plurality of electrical meters as described above with reference to FIGS. 8-15. Depending on the exact configuration of the system 1600, the memory 1604 may be volatile, such as RAM, non-volatile, such as ROM, flash memory, miniature hard drive, memory card, and the like, or some combination thereof. The memory 1604 may store computer-executable instructions that are executable by the processors 1602.

The components of the system 1600 coupled to the processors 1602 and the memory 1604 may comprise a user interface (UI) 1610, including a display 1612, and a communication module 1614. The communication module 1614 may communicate with a plurality of electricity meters 1616 to receive the voltage time series data collected as discussed above with reference to FIGS. 4-6, as indicated by an arrow 1618. Additionally, or alternatively, the electricity meters 1616 may communicate with a central office 1620 of the utility provider, or a third party, as shown by an arrow 1622, and the central office 1620 may collect the voltage time series data. The central office 1620 may communicate the collected voltage time series data to the communication module 1614 as shown by an arrow 1624. While the communications 1618, 1622, and 1624 between the communication module 1614 and the electricity meters 1616, the electricity meters 1616 and the central office 1620, and the central office 1620 and the communication module 1614, respectively, are shown as wireless communications, the communications 1618, 1622, and 1624 may be established in various ways, such as via a cellular network, Wi-Fi network, cable network, landline telephone network, and the like.

While not shown, each of the electricity meters 1616 may comprise one or more processors, memory coupled to the processors, a metrology module coupled to the processors, and a communication module coupled to the processors. The processors may include one or more central processing units (CPUs), graphics processing units (GPUs), both CPUs and GPUs, or other processing units or components known in the art. The processors may execute computer-executable instructions stored in the memory to perform functions or operations with one or more of components communicatively coupled to the one or more processors and the memory, such as measuring the voltage and storing voltage time series data in the memory or transmitting to the central office 1620 or to the communication module 1614 of the system 1600.

Depending on the exact configuration of the electricity meter 1616, the memory may be volatile, such as RAM, non-volatile, such as ROM, flash memory, miniature hard drive, memory card, and the like, or some combination thereof. The memory may store computer-executable instructions that are executable by the processors. The electricity meter 1616 may receive instructions from the central office 1620 regarding the preselected collection time period and the preselected interval, for example, changing the collection time period to two years and the interval to two minutes.

Some or all operations of the methods described above can be performed by execution of computer-readable instructions stored on a computer-readable storage medium, as defined below. The terms “computer-readable medium,” “computer-readable instructions,” and “computer executable instruction” as used in the description and claims, include routines, applications, application modules, program modules, programs, components, data structures, algorithms, and the like. Computer-readable and -executable instructions can be implemented on various system configurations, including single-processor or multiprocessor systems, minicomputers, mainframe computers, personal computers, hand-held computing devices, microprocessor-based, programmable consumer electronics, combinations thereof, and the like.

The computer-readable storage media may include volatile memory (such as random-access memory (RAM)) and/or non-volatile memory (such as read-only memory (ROM), flash memory, etc.). The computer-readable storage media may also include additional removable storage and/or non-removable storage including, but not limited to, flash memory, magnetic storage, optical storage, and/or tape storage that may provide non-volatile storage of computer-readable instructions, data structures, program modules, and the like.

A non-transitory computer-readable storage medium is an example of computer-readable media. Computer-readable media includes at least two types of computer-readable media, namely computer-readable storage media and communications media. Computer-readable storage media includes volatile and non-volatile, removable and non-removable media implemented in any process or technology for storage of information such as computer-readable instructions, data structures, program modules, or other data. Computer-readable storage media includes, but is not limited to, phase change memory (PRAM), static random-access memory (SRAM), dynamic random-access memory (DRAM), other types of random-access memory (RAM), read-only memory (ROM), electrically erasable programmable read-only memory (EEPROM), flash memory or other memory technology, compact disk read-only memory (CD-ROM), digital versatile disks (DVD) or other optical storage, magnetic cassettes, magnetic tape, magnetic disk storage or other magnetic storage devices, or any other non-transmission medium that can be used to store information for access by a computing device. In contrast, communication media may embody computer-readable instructions, data structures, program modules, or other data in a modulated data signal, such as a carrier wave, or other transmission mechanism. As defined herein, computer-readable storage media do not include signals such as communication media.

The computer-readable instructions stored on one or more non-transitory computer-readable storage media, when executed by one or more processors, may perform operations described above with reference to FIGS. 4-15. Generally, computer-readable instructions include routines, programs, objects, components, data structures, and the like that perform particular functions or implement particular abstract data types. The order in which the operations are described is not intended to be construed as a limitation, and any number of the described operations can be combined in any order and/or in parallel to implement the processes.

### Example Clauses

A. A method includes: predicting a phase correlated with each electricity meter of a plurality of electricity meters based on voltage time series data collected over a preselected collection time period, the phase being one of a first phase, a second phase, or a third phase; selecting a reliability parameter associated with predicted phases of the plurality of electricity meters; determining whether a parameter value associated with the reliability parameter meets a threshold parameter value; and one of: based on determining that the parameter value meets the threshold parameter value, determining that the predicted phases of the plurality of electricity meters are valid; or based on determining that the parameter value fails to meet the threshold parameter value, determining that the predicted phases of the plurality of electricity meters are invalid.

B. The method of example A, wherein selecting the reliability parameter associated with predicted phases of the plurality of electricity meters includes: generating a phase correlation plot by clustering correlations of the plurality of electricity meters into a first cluster, a second cluster, and a third cluster based on each phase corelated to the plurality of electricity meters; determining: a first phase correlation line associated with the first cluster, a second phase correlation line associated with the second cluster, and a third phase correlation line associated with the third cluster; determining an angle index associated with the plurality of electricity meters, the angle index being one of: a difference between a maximum separation angle and a minimum separation angle, a separation angle being an angle between adjacent phase correlation lines on the phase correlation plot, or a ratio of the minimum separation angle and the maximum separation angle; and setting the angle index as the reliability parameter.

C. The method of example B, wherein determining whether the parameter value associated with the reliability parameter meets the threshold parameter value includes: selecting a cutoff population of the plurality of electricity meters; determining a cutoff angle index corresponding to the cutoff population as the threshold parameter value; and determining whether the angle index is less than the cutoff angle index.

D. The method of example A, wherein selecting the reliability parameter associated with predicted phases of the plurality of electricity meters includes: determining: a first population of electricity meters of the plurality of electricity meters predicted as belonging to the first phase, a second population of electricity meters of the plurality of electricity meters predicted as belonging to the second phase, and a third population of electricity meters of the plurality of electricity meters predicted as belonging to the third phase; determining a minimum size of the first population of electricity meters, the second population of electricity meters, and the third population of electricity meters; determining a maximum size of the first population of electricity meters, the second population of electricity meters, and the third population of electricity meters; determining a balance index as a ratio of the minimum size and the maximum size; and setting the balance index as the reliability parameter.

E. The method of example D, wherein determining whether the parameter value associated with the reliability parameter meets the threshold parameter value includes determining whether the balance index is greater than a threshold balance index.

F. The method of example A, wherein selecting the reliability parameter associated with predicted phases of the plurality of electricity meters includes: selecting a sub-period of the preselected collection time period, the preselected collection time period comprising a plurality of sub-periods; for each electricity meter of the plurality of electricity meters, determining whether a sub-period predicted phase of the selected sub-period matches the predicted phase; determining a sub-period consistency as a ratio of a sub-period phase matching population of electricity meters having sub-period predicted phases matching corresponding predicted phases over a number of electricity meters in the plurality of electricity meters, and determining an average consistency by averaging sub-period consistencies over the preselected collection time period.

G. The method of example F, wherein determining whether the parameter value associated with the reliability parameter meets the threshold parameter value includes at least one of: determining whether the sub-period consistency is greater than a threshold sub-period consistency, or determining whether the average consistency is greater than a threshold average consistency.

H. The method of example A, wherein selecting the reliability parameter associated with predicted phases of the plurality of electricity meters includes: for each electricity meter, determining: based at least in part on a respective predicted phase, a first correlation with the first phase, a second correlation with the second phase, and a third correlation with the third phase, a highest correlation among the first correlation, the second correlation, and the third correlation, a median correlation among the first correlation, the second correlation, and the third correlation, and an individual confidence level based at least in part on the highest correlation, a first number of observations associated with the highest correlation, the median correlation, and a second number of observations associated with the median correlation; determining an average confidence level of the plurality of electricity meters based on individual confidence levels of the plurality of electricity meters; and setting the average confidence level as the reliability parameter.

I. The method of example H, wherein determining whether the parameter value associated with the reliability parameter meets the threshold parameter value includes determining whether the average confidence level is greater than a threshold confidence level.

J. A system including: one or more processors; and memory communicatively coupled to the one or more processors, the memory storing computer executable instructions that, when executed by the one or more processors, cause the one or more processors to perform operations comprising: predicting a phase correlated with each electricity meter of a plurality of electricity meters based on voltage time series data collected over a preselected collection time period, the phase being one of a first phase, a second phase, or a third phase; selecting a reliability parameter associated with predicted phases of the plurality of electricity meters; determining whether a parameter value associated with the reliability parameter meets a threshold parameter value; and one of: based on determining that the parameter value meets the threshold parameter value, determining that the predicted phases of the plurality of electricity meters are valid; or based on determining that the parameter value fails to meet the threshold parameter value, determining that the predicted phases of the plurality of electricity meters are invalid.

K. The system of example J, wherein: selecting the reliability parameter associated with predicted phases of the plurality of electricity meters includes: generating a phase correlation plot by clustering correlations of the plurality of electricity meters into a first cluster, a second cluster, and a third cluster based on each phase corelated to the plurality of electricity meters; determining: a first phase correlation line associated with the first cluster, a second phase correlation line associated with the second cluster, and a third phase correlation line associated with the third cluster; determining an angle index associated with the plurality of electricity meters, the angle index being one of: a difference between a maximum separation angle and a minimum separation angle, a separation angle being an angle between adjacent phase correlation lines on the phase correlation plot, or a ratio of the minimum separation angle and the maximum separation angle; and setting the angle index as the reliability parameter.

L. The system of example K, wherein determining whether the parameter value associated with the reliability parameter meets the threshold parameter value includes: selecting a cutoff population of the plurality of electricity meters; determining a cutoff angle index corresponding to the cutoff population as the threshold parameter value; and determining whether the angle index is less than the cutoff angle index.

M. The system of example J, wherein: selecting the reliability parameter associated with predicted phases of the plurality of electricity meters includes: determining: a first population of electricity meters of the plurality of electricity meters predicted as belonging to the first phase, a second population of electricity meters of the plurality of electricity meters predicted as belonging to the second phase, and a third population of electricity meters of the plurality of electricity meters predicted as belonging to the third phase; determining a minimum size of the first population of electricity meters, the second population of electricity meters, and the third population of electricity meters; determining a maximum size of the first population of electricity meters, the second population of electricity meters, and the third population of electricity meters; determining a balance index as a ratio of the minimum size and the maximum size; and setting the balance index as the reliability parameter, and determining whether the parameter value associated with the reliability parameter meets the threshold parameter value includes: determining whether the balance index is greater than a threshold balance index.

N. The system of example J, wherein: selecting the reliability parameter associated with predicted phases of the plurality of electricity meters includes: selecting a sub-period of the preselected collection time period, the preselected collection time period comprising a plurality of sub-periods; for each electricity meter of the plurality of electricity meters, determining whether a sub-period predicted phase of the selected sub-period matches the predicted phase; determining a sub-period consistency as a ratio of a sub-period phase matching population of electricity meters having sub-period predicted phases matching corresponding predicted phases over a number of electricity meters in the plurality of electricity meters, and determining an average consistency by averaging sub-period consistencies over the preselected collection time period, and determining whether the parameter value associated with the reliability parameter meets the threshold parameter value includes at least one of: determining whether the sub-period consistency is greater than a threshold sub-period consistency, or determining whether the average consistency is greater than a threshold average consistency.

O. The system of example J, wherein: selecting the reliability parameter associated with predicted phases of the plurality of electricity meters includes: for each electricity meter, determining: based at least in part on a respective predicted phase, a first correlation with the first phase, a second correlation with the second phase, and a third correlation with the third phase, a highest correlation among the first correlation, the second correlation, and the third correlation, a median correlation among the first correlation, the second correlation, and the third correlation, and an individual confidence level based at least in part on the highest correlation, a first number of observations associated with the highest correlation, the median correlation, and a second number of observations associated with the median correlation; determining an average confidence level of the plurality of electricity meters based on individual confidence levels of the plurality of electricity meters; and setting the average confidence level as the reliability parameter, and determining whether the parameter value associated with the reliability parameter meets the threshold parameter value includes: determining whether the average confidence level is greater than a threshold confidence level.

P. A non-transitory computer-readable storage medium storing computer executable instructions that, when executed by one or more processors of an electricity meter, cause the one or more processors to perform operations including: predicting a phase correlated with each electricity meter of a plurality of electricity meters based on voltage time series data collected over a preselected collection time period, the phase being one of a first phase, a second phase, or a third phase; selecting a reliability parameter associated with predicted phases of the plurality of electricity meters; determining whether a parameter value associated with the reliability parameter meets a threshold parameter value; and one of: based on determining that the parameter value meets the threshold parameter value, determining that the predicted phases of the plurality of electricity meters are valid; or based on determining that the parameter value fails to meet the threshold parameter value, determining that the predicted phases of the plurality of electricity meters are invalid.

Q. The non-transitory computer-readable storage medium of example P, wherein: selecting the reliability parameter associated with predicted phases of the plurality of electricity meters includes: generating a phase correlation plot by clustering correlations of the plurality of electricity meters into a first cluster, a second cluster, and a third cluster based on each phase corelated to the plurality of electricity meters; determining: a first phase correlation line associated with the first cluster, a second phase correlation line associated with the second cluster, and a third phase correlation line associated with the third cluster; determining an angle index associated with the plurality of electricity meters, the angle index being one of: a difference between a maximum separation angle and a minimum separation angle, a separation angle being an angle between adjacent phase correlation lines on the phase correlation plot, or a ratio of the minimum separation angle and the maximum separation angle; and setting the angle index as the reliability parameter, and determining whether the parameter value associated with the reliability parameter meets the threshold parameter value includes: selecting a cutoff population of the plurality of electricity meters; determining a cutoff angle index corresponding to the cutoff population as the threshold parameter value; and determining whether the angle index is less than the cutoff angle index.

R. The non-transitory computer-readable storage medium of example P, wherein: selecting the reliability parameter associated with predicted phases of the plurality of electricity meters includes: determining: a first population of electricity meters of the plurality of electricity meters predicted as belonging to the first phase, a second population of electricity meters of the plurality of electricity meters predicted as belonging to the second phase, and a third population of electricity meters of the plurality of electricity meters predicted as belonging to the third phase; determining a minimum size of the first population of electricity meters, the second population of electricity meters, and the third population of electricity meters; determining a maximum size of the first population of electricity meters, the second population of electricity meters, and the third population of electricity meters; determining a balance index as a ratio of the minimum size and the maximum size; and setting the balance index as the reliability parameter, and determining whether the parameter value associated with the reliability parameter meets the threshold parameter value includes: determining whether the balance index is greater than a threshold balance index.

S. The non-transitory computer-readable storage medium of example P, wherein: selecting the reliability parameter associated with predicted phases of the plurality of electricity meters includes: selecting a sub-period of the preselected collection time period, the preselected collection time period comprising a plurality of sub-periods; for each electricity meter of the plurality of electricity meters, determining whether a sub-period predicted phase of the selected sub-period matches the predicted phase; determining a sub-period consistency as a ratio of a sub-period phase matching population of electricity meters having sub-period predicted phases matching corresponding predicted phases over a number of electricity meters in the plurality of electricity meters, and determining an average consistency by averaging sub-period consistencies over the preselected collection time period, and determining whether the parameter value associated with the reliability parameter meets the threshold parameter value includes at least one of: determining whether the sub-period consistency is greater than a threshold sub-period consistency, or determining whether the average consistency is greater than a threshold average consistency.

T. The non-transitory computer-readable storage medium of example P, wherein: selecting the reliability parameter associated with predicted phases of the plurality of electricity meters includes: for each electricity meter, determining: based at least in part on the predicted phase, a first correlation with the first phase, a second correlation with the second phase, and a third correlation with the third phase, a highest correlation among the first correlation, the second correlation, and the third correlation, a median correlation among the first correlation, the second correlation, and the third correlation, and an individual confidence level based at least in part on the highest correlation, a first number of observations associated with the highest correlation, the median correlation, and a second number of observations associated with the median correlation; determining an average confidence level of the plurality of electricity meters based on individual confidence levels of the plurality of electricity meters; and setting the average confidence level as the reliability parameter, and determining whether the parameter value associated with the reliability parameter meets the threshold parameter value includes: determining whether the average confidence level is greater than a threshold confidence level.

### CONCLUSION

Although the subject matter has been described in language specific to structural features and/or methodological acts, it is to be understood that the subject matter defined in the appended claims is not necessarily limited to the specific features or acts described. Rather, the specific features and acts are disclosed as exemplary forms of implementing the claims.

What is claimed is:

1. A method comprising:
predicting a phase correlated with each electricity meter of a plurality of electricity meters based on voltage time series data collected over a preselected collection time period, the phase being one of a first phase, a second phase, or a third phase;
selecting a reliability parameter associated with predicted phases of the plurality of electricity meters;
determining whether a parameter value associated with the reliability parameter meets a threshold parameter value; and
one of:
based on determining that the parameter value meets the threshold parameter value, determining that the predicted phases of the plurality of electricity meters are valid; or
based on determining that the parameter value fails to meet the threshold parameter value, determining that the predicted phases of the plurality of electricity meters are invalid.

2. The method of claim 1, wherein selecting the reliability parameter associated with predicted phases of the plurality of electricity meters includes:
generating a phase correlation plot by clustering correlations of the plurality of electricity meters into a first cluster, a second cluster, and a third cluster based on each phase corelated to the plurality of electricity meters;
determining:
a first phase correlation line associated with the first cluster,
a second phase correlation line associated with the second cluster, and
a third phase correlation line associated with the third cluster;
determining an angle index associated with the plurality of electricity meters, the angle index being one of:
a difference between a maximum separation angle and a minimum separation angle, a separation angle being an angle between adjacent phase correlation lines on the phase correlation plot, or
a ratio of the minimum separation angle and the maximum separation angle; and
setting the angle index as the reliability parameter.

3. The method of claim 2, wherein determining whether the parameter value associated with the reliability parameter meets the threshold parameter value includes:
selecting a cutoff population of the plurality of electricity meters;
determining a cutoff angle index corresponding to the cutoff population as the threshold parameter value; and
determining whether the angle index is less than the cutoff angle index.

4. The method of claim 1, wherein selecting the reliability parameter associated with predicted phases of the plurality of electricity meters includes:
determining:
a first population of electricity meters of the plurality of electricity meters predicted as belonging to the first phase,
a second population of electricity meters of the plurality of electricity meters predicted as belonging to the second phase, and
a third population of electricity meters of the plurality of electricity meters predicted as belonging to the third phase;
determining a minimum size of the first population of electricity meters, the second population of electricity meters, and the third population of electricity meters;
determining a maximum size of the first population of electricity meters, the second population of electricity meters, and the third population of electricity meters;
determining a balance index as a ratio of the minimum size and the maximum size; and
setting the balance index as the reliability parameter.

5. The method of claim 4, wherein determining whether the parameter value associated with the reliability parameter meets the threshold parameter value includes:
determining whether the balance index is greater than a threshold balance index.

6. The method of claim 1, wherein selecting the reliability parameter associated with predicted phases of the plurality of electricity meters includes:
selecting a sub-period of the preselected collection time period, the preselected collection time period comprising a plurality of sub-periods;
for each electricity meter of the plurality of electricity meters, determining whether a sub-period predicted phase of the selected sub-period matches the predicted phase;
determining a sub-period consistency as a ratio of a sub-period phase matching population of electricity meters having sub-period predicted phases matching corresponding predicted phases over a number of electricity meters in the plurality of electricity meters; and
determining an average consistency by averaging sub-period consistencies over the preselected collection time period.

7. The method of claim 6, wherein determining whether the parameter value associated with the reliability parameter meets the threshold parameter value includes at least one of:
determining whether the sub-period consistency is greater than a threshold sub-period consistency, or
determining whether the average consistency is greater than a threshold average consistency.

8. The method of claim 1, wherein selecting the reliability parameter associated with predicted phases of the plurality of electricity meters includes:
for each electricity meter, determining:
based at least in part on a respective predicted phase,
a first correlation with the first phase,
a second correlation with the second phase, and
a third correlation with the third phase,
a highest correlation among the first correlation, the second correlation, and the third correlation,
a median correlation among the first correlation, the second correlation, and the third correlation, and
an individual confidence level based at least in part on the highest correlation, a first number of observations associated with the highest correlation, the median correlation, and a second number of observations associated with the median correlation;
determining an average confidence level of the plurality of electricity meters based on individual confidence levels of the plurality of electricity meters; and
setting the average confidence level as the reliability parameter.

9. The method of claim 8, wherein determining whether the parameter value associated with the reliability parameter meets the threshold parameter value includes:
determining whether the average confidence level is greater than a threshold confidence level.

10. A system comprising:
one or more processors; and
memory communicatively coupled to the one or more processors, the memory storing computer executable instructions that, when executed by the one or more processors, cause the one or more processors to perform operations comprising:
predicting a phase correlated with each electricity meter of a plurality of electricity meters based on voltage time series data collected over a preselected collection time period, the phase being one of a first phase, a second phase, or a third phase;
selecting a reliability parameter associated with predicted phases of the plurality of electricity meters;
determining whether a parameter value associated with the reliability parameter meets a threshold parameter value; and
one of:
based on determining that the parameter value meets the threshold parameter value, determining that the predicted phases of the plurality of electricity meters are valid; or
based on determining that the parameter value fails to meet the threshold parameter value, determining that the predicted phases of the plurality of electricity meters are invalid.

11. The system of claim 10, wherein:
selecting the reliability parameter associated with predicted phases of the plurality of electricity meters includes:
generating a phase correlation plot by clustering correlations of the plurality of electricity meters into a first cluster, a second cluster, and a third cluster based on each phase corelated to the plurality of electricity meters;
determining:
a first phase correlation line associated with the first cluster,
a second phase correlation line associated with the second cluster, and
a third phase correlation line associated with the third cluster;
determining an angle index associated with the plurality of electricity meters, the angle index being one of:
a difference between a maximum separation angle and a minimum separation angle, a separation angle being an angle between adjacent phase correlation lines on the phase correlation plot, or
a ratio of the minimum separation angle and the maximum separation angle; and
setting the angle index as the reliability parameter.

12. The system of claim 11, wherein determining whether the parameter value associated with the reliability parameter meets the threshold parameter value includes:
selecting a cutoff population of the plurality of electricity meters;
determining a cutoff angle index corresponding to the cutoff population as the threshold parameter value; and
determining whether the angle index is less than the cutoff angle index.

13. The system of claim 10, wherein:
selecting the reliability parameter associated with predicted phases of the plurality of electricity meters includes:
determining:
a first population of electricity meters of the plurality of electricity meters predicted as belonging to the first phase,
a second population of electricity meters of the plurality of electricity meters predicted as belonging to the second phase, and
a third population of electricity meters of the plurality of electricity meters predicted as belonging to the third phase;
determining a minimum size of the first population of electricity meters, the second population of electricity meters, and the third population of electricity meters;
determining a maximum size of the first population of electricity meters, the second population of electricity meters, and the third population of electricity meters;
determining a balance index as a ratio of the minimum size and the maximum size; and
setting the balance index as the reliability parameter, and
determining whether the parameter value associated with the reliability parameter meets the threshold parameter value includes:
determining whether the balance index is greater than a threshold balance index.

14. The system of claim 10, wherein:
selecting the reliability parameter associated with predicted phases of the plurality of electricity meters includes:
selecting a sub-period of the preselected collection time period, the preselected collection time period comprising a plurality of sub-periods;
for each electricity meter of the plurality of electricity meters, determining whether a sub-period predicted phase of the selected sub-period matches the predicted phase;
determining a sub-period consistency as a ratio of a sub-period phase matching population of electricity meters having sub-period predicted phases matching corresponding predicted phases over a number of electricity meters in the plurality of electricity meters, and
determining an average consistency by averaging sub-period consistencies over the preselected collection time period, and
determining whether the parameter value associated with the reliability parameter meets the threshold parameter value includes at least one of:
determining whether the sub-period consistency is greater than a threshold sub-period consistency, or
determining whether the average consistency is greater than a threshold average consistency.

15. The system of claim 10, wherein:
selecting the reliability parameter associated with predicted phases of the plurality of electricity meters includes:
for each electricity meter, determining:
based at least in part on a respective predicted phase,
a first correlation with the first phase,
a second correlation with the second phase, and
a third correlation with the third phase,
a highest correlation among the first correlation, the second correlation, and the third correlation,
a median correlation among the first correlation, the second correlation, and the third correlation, and
an individual confidence level based at least on part on the highest correlation, a first number of observations associated with the highest correlation, the median correlation, and a second number of observations associated with the median correlation;
determining an average confidence level of the plurality of electricity meters based on individual confidence levels of the plurality of electricity meters; and
setting the average confidence level as the reliability parameter, and
determining whether the parameter value associated with the reliability parameter meets the threshold parameter value includes:
determining whether the average confidence level is greater than a threshold confidence level.

16. A non-transitory computer-readable storage medium storing computer executable instructions that, when executed by one or more processors of an electricity meter, cause the one or more processors to perform operations comprising:
predicting a phase correlated with each electricity meter of a plurality of electricity meters based on voltage time series data collected over a preselected collection time period, the phase being one of a first phase, a second phase, or a third phase;
selecting a reliability parameter associated with predicted phases of the plurality of electricity meters;
determining whether a parameter value associated with the reliability parameter meets a threshold parameter value; and
one of:
based on determining that the parameter value meets the threshold parameter value, determining that the predicted phases of the plurality of electricity meters are valid; or
based on determining that the parameter value fails to meet the threshold parameter value, determining that the predicted phases of the plurality of electricity meters are invalid.

17. The non-transitory computer-readable storage medium of claim 16, wherein:
selecting the reliability parameter associated with predicted phases of the plurality of electricity meters includes:
generating a phase correlation plot by clustering correlations of the plurality of electricity meters into a first cluster, a second cluster, and a third cluster based on each phase corelated to the plurality of electricity meters;
determining:
a first phase correlation line associated with the first cluster,
a second phase correlation line associated with the second cluster, and
a third phase correlation line associated with the third cluster;
determining an angle index associated with the plurality of electricity meters, the angle index being one of:
a difference between a maximum separation angle and a minimum separation angle, a separation angle being an angle between adjacent phase correlation lines on the phase correlation plot, or
a ratio of the minimum separation angle and the maximum separation angle; and
setting the angle index as the reliability parameter, and determining whether the parameter value associated with the reliability parameter meets the threshold parameter value includes:
selecting a cutoff population of the plurality of electricity meters;
determining a cutoff angle index corresponding to the cutoff population as the threshold parameter value; and
determining whether the angle index is less than the cutoff angle index.

18. The non-transitory computer-readable storage medium of claim 16, wherein:
selecting the reliability parameter associated with predicted phases of the plurality of electricity meters includes:
determining:
a first population of electricity meters of the plurality of electricity meters predicted as belonging to the first phase,
a second population of electricity meters of the plurality of electricity meters predicted as belonging to the second phase, and
a third population of electricity meters of the plurality of electricity meters predicted as belonging to the third phase;
determining a minimum size of the first population of electricity meters, the second population of electricity meters, and the third population of electricity meters;
determining a maximum size of the first population of electricity meters, the second population of electricity meters, and the third population of electricity meters;
determining a balance index as a ratio of the minimum size and the maximum size; and
setting the balance index as the reliability parameter, and determining whether the parameter value associated with the reliability parameter meets the threshold parameter value includes:
determining whether the balance index is greater than a threshold balance index.

19. The non-transitory computer-readable storage medium of claim 16, wherein:
selecting the reliability parameter associated with predicted phases of the plurality of electricity meters includes:
selecting a sub-period of the preselected collection time period, the preselected collection time period comprising a plurality of sub-periods;
for each electricity meter of the plurality of electricity meters, determining whether a sub-period predicted phase of the selected sub-period matches the predicted phase;
determining a sub-period consistency as a ratio of a sub-period phase matching population of electricity meters having sub-period predicted phases matching corresponding predicted phases over a number of electricity meters in the plurality of electricity meters, and
determining an average consistency by averaging sub-period consistencies over the preselected collection time period, and
determining whether the parameter value associated with the reliability parameter meets the threshold parameter value includes at least one of:
determining whether the sub-period consistency is greater than a threshold sub-period consistency, or
determining whether the average consistency is greater than a threshold average consistency.

20. The non-transitory computer-readable storage medium of claim 16, wherein:
selecting the reliability parameter associated with predicted phases of the plurality of electricity meters includes:
for each electricity meter, determining:
based at least in part on the predicted phase,
a first correlation with the first phase,
a second correlation with the second phase, and
a third correlation with the third phase,
a highest correlation among the first correlation, the second correlation, and the third correlation,
a median correlation among the first correlation, the second correlation, and the third correlation, and
an individual confidence level based at least in part on the highest correlation, a first number of observations associated with the highest correlation, the median correlation, and a second number of observations associated with the median correlation;
determining an average confidence level of the plurality of electricity meters based on individual confidence levels of the plurality of electricity meters; and
setting the average confidence level as the reliability parameter, and
determining whether the parameter value associated with the reliability parameter meets the threshold parameter value includes:
determining whether the average confidence level is greater than a threshold confidence level.
